(19) United States
(12) Patent Application Publication
(10) Pub. No.: US 2008/0314408 A1
(43) Pub. Date: Dec. 25, 2008

(54) Plasma etching apparatus and chamber cleaning method using the same

(75) Inventors: Sang Min Jeong, Seoul (KR); Doug Yong Sung, Suwon-si (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 12/081,407

(22) Filed: Apr. 15, 2008

(30) Foreign Application Priority Data
Jun. 19, 2007 (KR) 10-2007-59802

(51) Int. Cl. C25F 1/00; H01L 21/3065

(52) U.S. Cl. 134/1.1; 156/345.28

(57) ABSTRACT

The plasma etching apparatus effectively removes an outgrowth caused by the etching in the chamber after performing a fabrication process, and a chamber cleaning method using the plasma etching apparatus. The plasma etching apparatus includes: a chamber in which an etching process of a substrate is conducted using a plasma; upper and lower electrodes arranged in the chamber; a RF power-supply unit which simultaneously applies a RF power to the upper and lower electrodes; and a controller which adjusts a power ratio of the RF power simultaneously applied to the upper and lower electrodes, and controls a plasma distribution for cleaning an inner part of the chamber. As a result, the plasma is evenly formed in the chamber, so that a cleaning efficiency can be maximized.

### CROSS-REFERENCE TO RELATED APPLICATIONS

This application claims the benefit of Korean Patent Application No. 2007˜0059802, filed on Jun. 19, 2007 in the Korean Intellectual Property Office, the disclosure of which is incorporated herein by reference.

### BACKGROUND

1. Field

The present invention relates to a method for manufacturing a semiconductor using plasma, and more particularly to a plasma etching apparatus for effectively removing an outgrowth caused by the etching in the chamber after performing a fabrication process, and a chamber cleaning method using the plasma etching apparatus.

2. Description of the Related Art

Generally, the semiconductor fabrication process includes a thin film forming process for forming a thin film on a semiconductor substrate, a light-exposure process for forming a mask pattern on a thin film to form a fine pattern, and an etching process for forming a fine pattern by etching the thin film.

Recently, as the integration degree of the semiconductor element gradually increases, a line width of the fine pattern gradually decreases, so that the importance of the etching apparatus for use in the etching process for forming the fine pattern becomes higher. A variety of etching apparatuses have been widely used, and a representative example of the etching apparatus is a Capacitive Coupled Plasma (CCP) processing apparatus for processing the semiconductor substrate using the plasma.

The above-mentioned plasma etching apparatus applies a compound including a high-reactivity halogen to a location between two electrodes of the chamber, and at the same time applies a RF power to either one of the two electrodes. In this case, the compound is used as the etching gas between the two electrodes. So, the RF electric field is formed between the two electrodes, the etching gas applied to the chamber forms the plasma status, and the etching process of the semiconductor substrate is conducted using activated ions.

If the etching process begins, most materials etched from the surface of the semiconductor substrate are discharged to the outside of the chamber, however, some materials (i.e., etching outgrowths) are adsorbed on the inner wall of the chamber, and remain in the chamber.

If the next etching process begins under the condition that the outgrowths have been adsorbed on the inner wall of the chamber, the activated ions of the plasma status reacts to the outgrowths adsorbed on the inner wall of the chamber, the outgrowths are removed from the inner wall of the chamber, and are adsorbed on the semiconductor substrate, so that the etching process becomes unstable and the pollution of the semiconductor substrate occurs.

Therefore, the inner part of the chamber is periodically cleaned to remove the etching outgrowth, and then the etching process must be conducted.

In order to solve the above-mentioned problem, a cleaning method for removing the outgrowth from the inner wall of the chamber has been proposed, which forms the plasma in the empty chamber to remove the outgrowth from the inner wall of the chamber, while unloading the semiconductor substrate where the etching process has been completed, and then loading the semiconductor substrate for the next etching process. A plasma etching apparatus for the above-mentioned cleaning method has been disclosed in U.S. Pat. Nos. 6,849,154 and 4,579,618.

The above-mentioned cleaning method disclosed in U.S. Pat. No. 6,849,154 applies the RF power to the upper electrode of the chamber so as to form the plasma. Although this method can effectively remove upper outgrowths, it cannot remove the etching outgrowth such as a polymer deposited on the lower electrode.

The above-mentioned cleaning method disclosed in U.S. Pat. No. 4,579,618 applies the RF power to the lower electrode of the chamber so as to form the plasma. Although this method can effectively remove lower outgrowths, it cannot remove the etching outgrowth such as a polymer deposited on the upper electrode.

### SUMMARY

Therefore, it is an aspect of the invention to provide a plasma etching apparatus for effectively removing the etching outgrowth from the chamber after performing the etching process based on the plasma, and a chamber cleaning method using the plasma etching apparatus.

It is another aspect of the invention to provide a plasma etching apparatus for simultaneously applying a RF power of at least 60 MHz to upper and lower electrodes so as to remove the etching outgrowth from the chamber, uniformly forming the plasma in the chamber, and maximizing the cleaning efficiency, and a chamber cleaning method using the plasma etching apparatus.

It is yet another aspect of the invention to provide a plasma etching apparatus for controlling the plasma distribution via a phase difference on the condition that the frequencies of the RF powers applied to the upper and lower electrodes are equal to each other, selectively cleaning the inner part of the chamber, and a chamber cleaning method using the plasma etching apparatus.

Additional aspects and/or advantages of the invention will be set forth in part in the description which follows and, in part, will be apparent from the description, or may be learned by practice of the invention.

In accordance with the invention, the above and/or other aspects can be achieved by the provision of a plasma etching apparatus including: a chamber in which an etching process of a substrate is conducted using a plasma; upper and lower electrodes arranged in the chamber; a RF power-supply unit which simultaneously applies a RF power to the upper and lower electrodes; and a controller which adjusts a power ratio of the RF power simultaneously applied to the upper and lower electrodes, and controls a plasma distribution for cleaning an inner part of the chamber.

The RF power simultaneously applied to the upper and lower electrodes may be a RF source power for removing an etching outgrowth of the chamber after performing the etching process to the substrate.

The RF source power may be about 0 W˜1000 W.

The controller may adjust a power ratio of the RF source power applied to the upper and lower electrodes, and control the plasma distribution to face upper and lower parts inside of the chamber.

The RF source power may have a frequency of at least 60 MHz.

If the frequencies of the RF source powers applied to the upper and lower electrodes are equal to each other, the controller may adjust a phase difference between the RF source powers.

The phase difference may be 0°˜180°.

The controller may adjust a phase difference of the RF source powers applied to the upper and lower electrodes, and allows the plasma distribution to face the center and outside of the chamber.

In accordance with another aspect of the present invention, there is provided a chamber cleaning method of a plasma etching apparatus including: simultaneously applying a RF power to the upper and lower electrodes arranged in the chamber in which the etching process of the substrate is conducted using the plasma; and adjusting a power ratio of the RF power simultaneously applied to the upper and lower electrodes, and controlling a plasma distribution for cleaning an inner part of the chamber.

The simultaneously applying of the RF power to the upper and lower electrodes may include simultaneously applying a RF source power to the upper and lower electrodes so as to remove an etching outgrowth of the chamber, after performing the etching process the substrate.

The controlling of the plasma distribution for cleaning the inner part of the chamber may include adjusting a power ratio of the RF source power applied to the upper and lower electrodes, and controlling the plasma distribution to face upper and lower parts inside of the chamber.

The controlling of the plasma distribution for cleaning the inner part of the chamber may include if the frequencies of the RF source powers applied to the upper and lower electrodes are equal to each other, adjusting a phase difference between the RF source powers, thereby allowing the plasma distribution to face the center and outside of the chamber.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a conceptual diagram illustrating a power-supply system for cleaning the chamber in the plasma etching apparatus according to a first embodiment of the present invention;

FIG. 2 is a conceptual diagram illustrating a power-supply system for cleaning the chamber in the plasma etching apparatus according to a second embodiment of the present invention;

FIG. 3 is a flow chart illustrating a chamber cleaning method using the plasma etching apparatus according to the first and second embodiments of the present invention;

FIG. 4 is a conceptual diagram illustrating a plasma forming process for cleaning the chamber in the plasma etching apparatus according to a first embodiment of the present invention;

FIG. 5 is a conceptual diagram illustrating a plasma forming process for cleaning the chamber in the plasma etching apparatus according to a second embodiment of the present invention; and

FIGS. 6 and 7 are graphs illustrating the polymer etching rate (PR E/R) for each location inside of the chamber according to the frequency applying method.

### DETAILED DESCRIPTION OF THE EMBODIMENTS

Reference will now be made in detail to the embodiments of the present invention, examples of which are illustrated in the accompanying drawings, wherein like reference numerals refer to like elements throughout. The embodiments are described below to explain the present invention by referring to the figures.

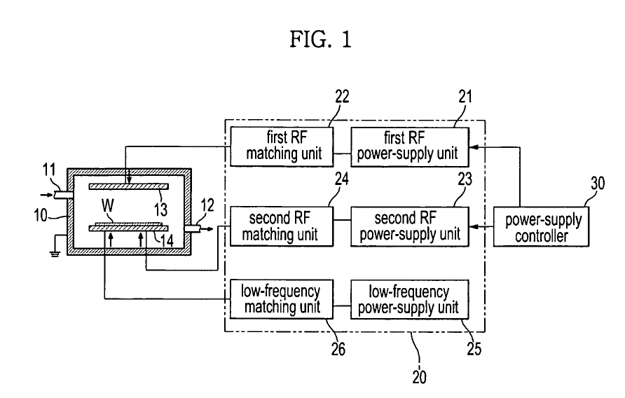

FIG. 1 is a conceptual diagram illustrating a power-supply system for cleaning the chamber in the plasma etching apparatus according to a first embodiment of the present invention.

Referring to FIG. 1, the plasma etching apparatus includes a chamber 10, a power-supply unit 20, and a power-supply controller 30.

The chamber 10 is a vacuum-status processing chamber in which the semiconductor fabrication process based on the plasma is conducted, and acts as a reactor for etching/cleaning a wafer (W) used as the semiconductor substrate. In the chamber 10, a gas inlet 11 and a gas outlet 12 are formed, the gas (e.g., the etching gas for the etching process or O2 gas for the cleaning process) supplied from the gas inlet 11 is excited into the plasma status by the RF power, so that the etching/cleaning process of the wafer (W) is conducted.

The chamber 10 includes an upper electrode 13 and a lower electrode 14, which simultaneously receive the RF source power of at least 60 MHz (about 60˜200 MHz), so that it forms the plasma in the cleaning process. The upper electrode 13 and the lower electrode 14 face each other.

The upper electrode 13 is a flat-type conductor which is located at an upper part of the chamber 10, so that it provides the chamber 10 with the RF source power of 60˜200 MHz.

The lower electrode 14 is located at a lower part of the chamber 10, and is arranged in parallel to the upper electrode 13. During the cleaning process, the lower electrode 14 receives the RF source power of 60˜200 MHz. During the etching process, the lower electrode 14 is a flat-type conductor receiving a low-frequency bias power of 2˜13.56 MHz. A target object (e.g., wafer (W)) to be processed is placed on the lower electrode 14.

The power-supply unit 20 applies the RF power or low-frequency power to the upper and lower electrodes 13 and 14 to excite the gas of the chamber into the plasma status. The RF power-supply unit 20 includes a first RF power-supply unit 21 for providing a first RF power (60˜200 MHz) acting as the RF source power to the upper electrode 13, a second RF power-supply unit 23 for providing a second RF power (60˜200 MHz) acting as a RF source power to the lower electrode 14, and a low-frequency power-supply unit 25 for providing a low-frequency power (2˜13.56 MHz) acting as the low-frequency bias power to the lower electrode. First and second RF matching units 22 and 24, and the low-frequency matching unit 26 are connected to the first and second RF power-supply units 21 and 23, and the low-frequency power-supply unit 25, respectively. The first and second RF matching units 22 and 24, and the low-frequency matching unit 26 perform the impedance matching, so that maximum powers of the first and second RF powers and the low-frequency power are applied to the upper and lower electrodes 13 and 14, respectively.

The power-supply controller 30 adjusts the power-supply ratio of the first and second RF powers applied to the upper and lower electrodes 13 and 14, controls the plasma distribution to face upper and lower parts of the chamber 10, so that the upper or lower parts of the chamber 10 is selectively cleaned.

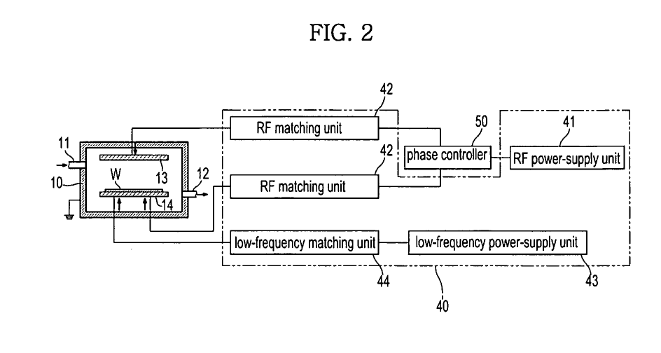

FIG. 2 is a conceptual diagram illustrating a power-supply system for cleaning the chamber in the plasma etching apparatus according to a second embodiment of the present invention.

Referring to FIG. 2, the plasma etching apparatus according to the present invention includes a chamber 10, a power-supply unit 40, and a phase controller 50.

The power-supply unit 40 applies the RF power or low-frequency power to the upper and lower electrodes 13 and 14 to excite the gas of the chamber into the plasma status. The RF power-supply unit 40 includes a RF power-supply unit 41 for providing the same RF power (having the frequency of 60˜200 MHz) acting as the RF source power to the upper and lower electrodes 13 and 14, a low-frequency power-supply unit 43 for providing a low-frequency power (2˜13.56 MHz) acting as a low-frequency bias power to the lower electrode 14. The RF matching unit 42 and the low-frequency matching unit 44 are connected to the RF power-supply unit 41 and the low-frequency power-supply unit 43, respectively. The RF matching unit 42 and the low-frequency matching unit 44 perform the impedance matching, so that maximum powers of the matching units 42 and 44 are applied to the upper and lower electrodes 13 and 14, respectively.

The phase controller 50 selectively cleans the upper or lower part of the chamber 10 by adjusting the power ratio of the RF power applied to the upper and lower electrodes 13 and 14, or adjusts the phase difference of the RF power applied to the upper and lower electrodes 13 and 14 in the range from 0° to 180°, so that the phase controller 50 allows the plasma distribution to face the center and outside of the chamber 10. As a result, the center and outside of the chamber 10 can be selectively cleaned.

Operations and effects of the plasma etching apparatus and the chamber cleaning method using the same will hereinafter be described.

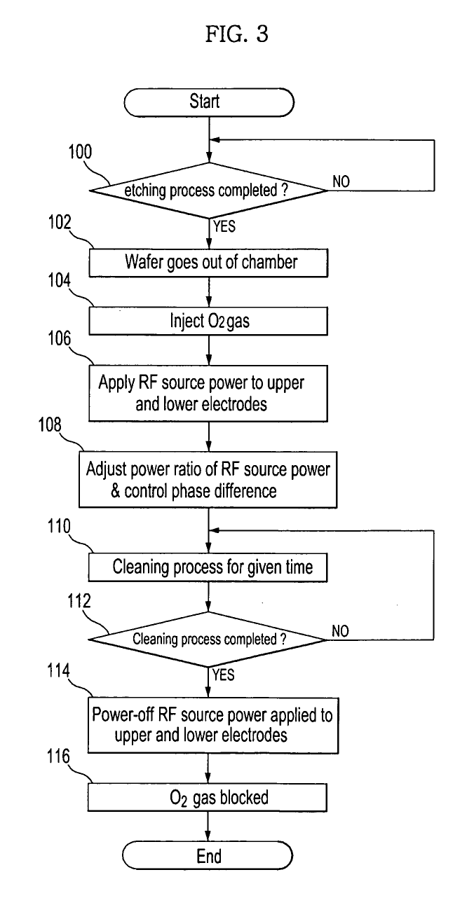

FIG. 3 is a flow chart illustrating a chamber cleaning method using the plasma etching apparatus according to the first and second embodiments of the present invention. FIG. 3 shows the cleaning process for removing the etching outgrowth of the chamber 10 after performing the etching process using the plasma.

If the etching process of the wafer (W) using the plasma is completed at operation 100, the completely-etched wafer (W) goes out of the chamber 10 at operation 102.

In this case, the outgrowth etched from the wafer (W) surface is adsorbed on the inner wall of the chamber 10, and remain in the chamber 10.

Therefore, O₂ gas for the cleaning process is generated from the gas provider (not shown), and is injected in the chamber 10 via the gas inlet 11 at 500˜2000 sccm, so that the fabrication pressure is adjusted to 50˜300 mT at operation 104.

While the O₂ gas for the cleaning process is injected into the empty chamber 10, the RF source power (about 0˜1000 W) with the frequency 60˜200 MHz is simultaneously applied to the upper and lower electrodes 13 and 14, so that the plasma is formed in the empty chamber at operation 106.

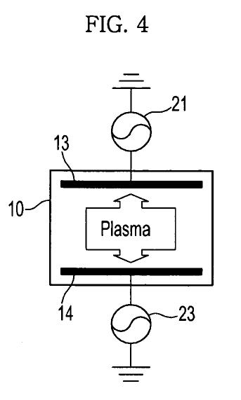

If the RF source powers applied to the upper and lower electrodes 13 and 14 have different frequencies, the power-supply controller 30 of FIG. 1 adjusts the power ratio of the RF source powers applied from the first and second RF power-supply units 21 and 23 to the upper and lower electrodes 13 and 14 via the first and second RF matching units 22 and 24, so that it controls the plasma distribution to face the upper and lower parts of the chamber 19 as shown in FIG. 4. Therefore, the upper or lower part of the chamber 10 is selectively cleaned.

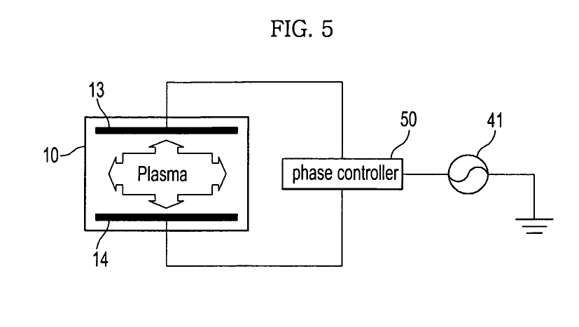

Otherwise, if the RF source powers applied to the upper and lower electrodes 13 and 14 have the same frequency, the phase controller 50 of FIG. 2 adjusts the power ratio of the RF source powers applied from the RF power-supply unit 41 to the upper and lower electrodes 13 and 14 via the RF matching unit 42, so that it selectively cleans the upper or lower part of the chamber 10 as shown in FIG. 5, or adjusts the phase difference of the RF source powers applied to the upper and lower electrodes 13 and 14 in the range from 0°, to 180° at operation 108.

If the cleaning process is conducted for a given period of time at operation 110, and is then completed at operation 112, the power-supply unit 30 of FIG. 1 and the phase controller 50 of FIG. 2 power off the RF source powers applied to the upper and lower electrodes 13 and 14 at operation 114. Simultaneously, the O₂ gas injected into the chamber 10 via the gas inlet 11 is blocked at operation 116, so that the cleaning process of the chamber 10 is completed. Then, the wafer (W) for the next etching process is seated in the chamber 10, so that the next etching process is conducted on the wafer (W).

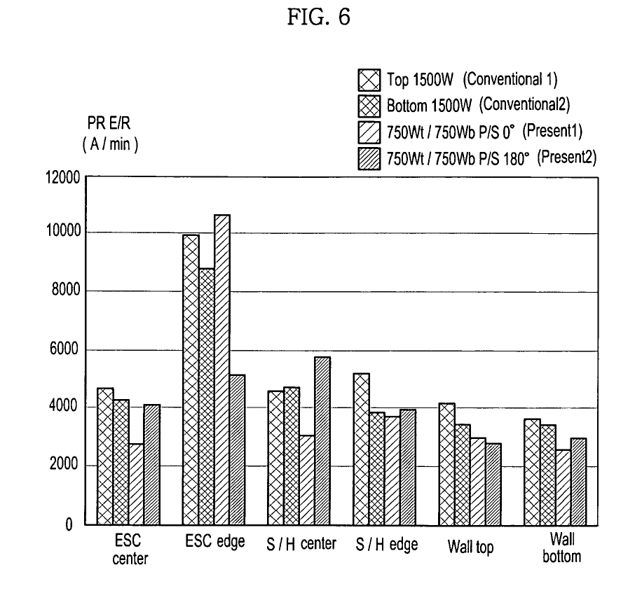

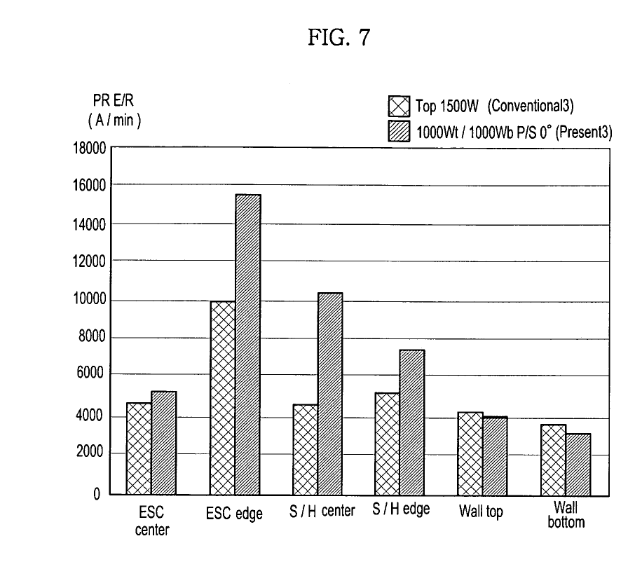

FIGS. 6 and 7 are graphs illustrating the polymer etching rate (PR E/R) for each location inside of the chamber according to the frequency applying method. The horizontal axis of each graph of FIG. 6 or 7 indicates the location in the chamber 10, and the vertical axis of the same indicates a polymer etching ratio (PR E/R).

A first conventional art (Conventional 1) of FIG. 6 indicates the polymer etching ratio (PR E/R) when the RF power of 1500 W is applied to only the upper electrode 13. A second conventional art (Conventional 2) of FIG. 6 indicates the polymer etching ratio (PR E/R) when the RF power of 1500 W is applied to only the lower electrode 14. A first present invention (Present 1) of FIG. 6 indicates the polymer etching ratio (PR E/R) when the RF power of 750 W is applied to each of the upper and lower electrodes 13 and 14 and the phase difference is 0°. A second present invention (Present 2) of FIG. 6 indicates the polymer etching ratio (PR E/R) when the RF power of 750 W is applied to each of the upper and lower electrodes 13 and 14 and the phase difference is 180°.

A third conventional art (Conventional 3) of FIG. 7 indicates the polymer etching ratio (PR E/R) when the RF power of 1500 W is applied to only the upper electrode 13. A third present invention (Present 3) of FIG. 7 indicates the polymer etching ratio (PR E/R) when the RF power of 1000 W is applied to each of the upper and lower electrodes 13 and 14 and the phase difference is 0°.

As can be seen from FIGS. 6 and 7, if the phase difference is 0°, the highest polymer etching rate is acquired from the lower ESC edge part. If the phase difference is 180°, the highest polymer etching rate is acquired from the upper showerhead (S/H) center part. So, it can be easily recognized that the high cleaning efficiency is acquired from the ESC edge part and the S/H center part which have the highest necessity of cleaning the inner part of the chamber 10.

As is apparent from the above description, the plasma etching apparatus and method according to the present invention effectively removes the etching outgrowth from the chamber after performing the etching process based on the plasma. The plasma etching apparatus simultaneously applies a RF power of at least 60 MHz to upper and lower electrodes so as to remove the etching outgrowth from the chamber, uniformly forms the plasma in the chamber, and maximizing the cleaning efficiency.

If the frequencies of the RF powers applied to the upper and lower electrodes are equal to each other, the plasma etching apparatus controls the plasma distribution via a phase difference, thereby selectively cleaning the inner part of the chamber.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A plasma etching apparatus comprising:
a chamber in which an etching process of a substrate is conducted using a plasma;
upper and lower electrodes arranged in the chamber;
a RF power-supply unit which simultaneously applies a RF power to the upper and lower electrodes; and
a controller which adjusts a power ratio of the RF power simultaneously applied to the upper and lower electrodes, and controls a plasma distribution for cleaning an inner part of the chamber.

2. The apparatus according to claim 1, wherein the RF power simultaneously applied to the upper and lower electrodes is a RF source power for removing an etching outgrowth of the chamber after performing the etching process the substrate.

3. The apparatus according to claim 2, wherein the RF source power is about 0 W˜1000 W.

4. The apparatus according to claim 3, wherein the controller adjusts a power ratio of the RF source power applied to the upper and lower electrodes, and controls the plasma distribution to face upper and lower parts inside of the chamber.

5. The apparatus according to claim 2, wherein the RF source power has a frequency of at least 60 MHz.

6. The apparatus according to claim 5, wherein if the frequencies of the RF source powers applied to the upper and lower electrodes are equal to each other, the controller adjusts a phase difference between the RF source powers.

7. The apparatus according to claim 6, wherein the phase difference is 0°˜180°.

8. The apparatus according to claim 6, wherein the controller adjusts a phase difference of the RF source powers applied to the upper and lower electrodes, and controls the plasma distribution to face the center and outside of the chamber.

9. A chamber cleaning method of a plasma etching apparatus comprising:
simultaneously applying a RF power to the upper and lower electrodes arranged in the chamber in which the etching process of the substrate is conducted using the plasma; and
adjusting a power ratio of the RF power simultaneously applied to the upper and lower electrodes, and controlling a plasma distribution for cleaning an inner part of the chamber.

10. The method according to claim 9, wherein the simultaneously applying of the RF power to the upper and lower electrodes includes simultaneously applying a RF source power to the upper and lower electrodes so as to remove an etching outgrowth of the chamber, after performing the etching process to the substrate.

11. The method according to claim 10, wherein the RF source power is about 0 W˜1000 W.

12. The method according to claim 11, wherein the controlling of the plasma distribution for cleaning the inner part of the chamber includes adjusting a power ratio of the RF source power simultaneously applied to the upper and lower electrodes, and controlling the plasma distribution to face upper and lower parts inside of the chamber.

13. The method according to claim 10, wherein the RF source power has a frequency of at least 60 MHz.

14. The method according to claim 13, wherein the controlling of the plasma distribution for cleaning the inner part of the chamber includes if the frequencies of the RF source powers simultaneously applied to the upper and lower electrodes are equal to each other, adjusting a phase difference between the RF source powers, thereby controlling the plasma distribution to face the center and outside of the chamber.

15. The method according to claim 14, wherein the phase difference is 0°˜180°.

16. The apparatus according to claim 1, wherein the RF power-supply unit comprises:
a first RF power-supply unit to provide a first RF power to the upper electrode;
a second RF power-supply unit to provide a second RF power to the lower electrode;
a low-frequency power-supply unit to provide a low-frequency power to the lower electrode;
first and second RF matching units connected to the first and second RF power-supply units, respectively; and
a low-frequency matching unit connected to the low-frequency power-supply unit,
wherein the first and second RF matching units, and the low-frequency matching unit, perform the impedance matching, so that maximum powers of the first and second RF powers and the low-frequency power are applied to the upper and lower electrodes, respectively.

17. The apparatus according to claim 16, wherein the first and second RF power is 60˜200 MHz.

18. The apparatus according to claim 16, wherein the low-frequency power is 2˜13.56 MHz.
